(19) United States
(12) Patent Application Publication
(10) Pub. No.: US 2025/0380362 A1
(43) Pub. Date: Dec. 11, 2025

(54) CIRCUIT ASSEMBLY WITH TWO CIRCUIT CARRIERS AND A SEMICONDUCTOR COMPONENT

(71) Applicant: SIEMENS AKTIENGESELLSCHAFT, München (DE)

(72) Inventors: Thomas BIGL, Herzogenaurach (DE); Stefan PFEFFERLEIN, Heroldsberg (DE); Alexander HENSLER, Gerhardshofen (DE); Bernd MÜLLER, Falkenberg (DE); Philipp OSCHMANN, Erlangen (DE); Jörg STROGIES, Berlin (DE)

(73) Assignee: Siemens Aktiengesellschaft, München (DE)

(21) Appl. No.: 18/877,061

(22) PCT Filed: May 10, 2023
(86) PCT No.: PCT/EP2023/062338

§ 371 Date: Dec. 19, 2024

(30) Foreign Application Priority Data
Jun. 20, 2022 (EP) 22179921.6

(51) Int. Cl. H05K 1/14; H05K 1/11

(52) U.S. Cl. CPC H05K 1/144; H05K 1/115; H05K 2201/042

(57) ABSTRACT

A circuit assembly includes first and second circuit carriers and a semiconductor component arranged between the circuit carriers and having first and second load terminals. The first load terminal has a first load terminal surface which faces the first circuit carrier and around which an electrically insulating edging structure is arranged. The second load terminal has a second load terminal surface which faces the second circuit carrier and is larger than the first load terminal surface. The first circuit carrier has a first through-contact which electrically connects the first load terminal surface to a first conductor path, which runs inside the first circuit carrier or on a top side of the first circuit carrier facing away from the semiconductor component. The second circuit carrier has a top side facing the semiconductor component and formed by a first electrically conductive layer that is electrically connected to the second load terminal surface.

The invention relates to a circuit assembly with two circuit carriers and at least one semiconductor component. The semiconductor component is, in particular, a power semiconductor.

In the field of power electronics, semiconductor components, for example switching elements, exist, as a rule, in the form of power modules, also referred to as power modules, or in the form of discrete packages. The semiconductor components are usually contacted by means of specific wire-bonding technologies and the power modules are attached to a circuit carrier, for example, by means of solder, groove or crimp connections. The use of bonding wires limits the maximum admissible current density through the semiconductor components. In addition, parasitic inductances occur which restrict an attainable switching speed of the switching elements.

WO 2020/249479 A1 discloses an electronic switching circuit which has, inter alia, a first circuit carrier, a second circuit carrier and a power-electronic semiconductor component. The semiconductor component has a top side which abuts an underside of the first circuit carrier, and an underside which abuts a top side of the second circuit carrier. The first circuit carrier has a through-contact (also referred to as a via) which electrically connects the top side of the first semiconductor component to a conductor path of the first circuit carrier. The second circuit carrier has, for example, an electrically conductive layer forming its top side and an electrically insulating layer arranged on a side of the electrically conductive layer remote from the first circuit carrier.

WO 2014/197917 A1 discloses a power module with a printed circuit board core which contains at least one electronic power component embedded in an insulating layer. The core is arranged between two heat dissipation plates, wherein each heat dissipation plate possesses a metallic outer layer and a metallic inner layer electrically isolated from it by a heat-conducting, electrically insulating intermediate layer.

DE 10 2021 125 094 A1 discloses a semiconductor package with a carrier and a semiconductor chip. The carrier has an electrically insulating body and a contact structure on one side of the electrically insulating body. The semiconductor chip has a pad which is attached to the contact structure of the carrier, wherein the pad is at source or emitter potential. The pad is inwardly spaced apart from an edge of the semiconductor chip by a first spacing. The semiconductor chip has an edging region between the edge and the pad. The contact structure of the carrier is inwardly spaced part from the edge of the semiconductor chip by a second spacing which is larger than the first spacing.

US 2012/243192 A1 discloses a three-dimensional power electronics package with a metallized substrate assembly, a first power electronics apparatus and a second power electronics apparatus. The metallized substrate assembly comprises an Insulating dielectric substrate with a current feedthrough which extends fully through the insulating dielectric substrate, a first conductive layer on a first surface of the insulating dielectric substrate and a second conductive layer on a second surface of the insulating dielectric substrate. The first conductive layer is electrically coupled to the second conductive layer by the feedthrough.

The invention is based on the object of disclosing an improved circuit assembly with two circuit carriers and at least one semiconductor component.

The object is inventively achieved by a circuit assembly with the features of claim 1.

Advantageous embodiments of the invention are the subject matter of the subclaims.

An inventive circuit assembly comprises
an at least two-layer first circuit carrier,
a second circuit carrier and
a semiconductor component arranged between the first circuit carrier and the second circuit carrier, with a first load terminal and a second load terminal, wherein
the first load terminal has a first load terminal surface facing the first circuit carrier, around which surface an electrically insulating edging structure is arranged,
the second load terminal has a second load terminal surface facing the second circuit carrier, which surface is larger than the first load terminal surface,
on a underside facing the semiconductor component, the first circuit carrier has a first load terminal contact pad which is electrically connected to the first load terminal surface,
the first circuit carrier has at least one first through-contact which connects the first load terminal contact pad to at least one first conductor path which runs inside the first circuit carrier or on an top side of the first circuit carrier remote from the semiconductor component, and
the second circuit carrier has a top side facing the semiconductor component, which side is formed by a first electrically conductive layer which is electrically connected to the second load terminal surface.

The terms “top side” and “underside” should not be understood as being limiting, rather they are oriented towards the representations in the figure. Further, the wording that the circuit assembly has one semiconductor component does not preclude the circuit assembly from having a plurality of semiconductor components. Therefore, the circuit assembly has at least one semiconductor component with the disclosed properties.

The semiconductor component has two load terminals which are arranged on different sides of the semiconductor component. The load terminals are not contacted via bonding wires, rather the first load terminal is contacted by the first load terminal contact pad of the first circuit carrier and the second load terminal is contacted by the first electrically conductive layer of the second circuit carrier (what is known as flip-chip technology). The first load terminal contact pad is connected, moreover, by at least one first through-contact to at least one first conductor path which runs in an inner layer or in an outer layer of the first circuit carrier remote from the semiconductor component. As a result, limitations, due to bonding wires, on the maximum admissible current density of a current through the semiconductor component and the switching speed of the semiconductor component advantageously do not apply. The semiconductor component can be, for example, a transistor, a thyristor or a diode.

A fundamental feature of the inventive circuit assembly is, moreover, that the first load terminal faces the first circuit carrier and the second load terminal faces the second circuit carrier, with the first load terminal being that load terminal whose load terminal surface is surrounded by the edging structure. The edging structure serves to reduce the difference in potential between the two load terminals.

By contrast, in the assembly known from the prior art according to WO 2020/249479 A1, the first load terminal faces the second circuit carrier and is electrically connected to its first electrically conductive layer. Since the potential of the second load terminal is applied at the outer edges of the edging structure, in the assembly known from the art an adequate spacing of the first load terminal from the second circuit carrier is necessary since its extensive first electrically conductive layer is at the potential of the first load terminal. The required spacing depends on the insulation material used and the reverse voltage of the semiconductor component. In order to adhere to this spacing, for example sintering paste deposits, sintering preforms or soldering preforms with a spacer function are used and/or the edging structure is electrically insulated from the first electrically conductive layer of the second circuit carrier by way of a passivation structure and/or a suitable casting material, which has to be cast in a laborious casting process adapted and matched to the casting material. This problem is rectified by the inventive assembly firstly in that the second load terminal is arranged on the second circuit carrier instead of the first load terminal, and secondly in that the first load terminal is connected by at least one first through-contact to at least one conductor path which runs inside or on the top side of the first circuit carrier, whereby the substrate (base material) of the first circuit carrier provides an additional insulating layer between each of these conductor paths and the edging structure of the semiconductor component. Compared to the assembly known from WO 2020/249479 A1, this simplifies production of the circuit assembly and enables a more compact form of the circuit assembly since the spacings of the semiconductor component from the circuit carriers can be reduced.

In one embodiment of the invention, the first load terminal contact pad is arranged completely within a region of the underside of the first circuit carrier which corresponds to a region of the semiconductor component surrounded by the edging structure. The region of the underside of the first circuit carrier, which corresponds to the region of the semiconductor component surrounded by the edging structure, designates a region of the underside of the first circuit carrier on which the region of the semiconductor component surrounded by the edging structure is indicated by a parallel displacement along a straight line parallel to a normal vector of the underside of the first circuit carrier. The region of the underside of the first circuit carrier corresponding to the region of the semiconductor component surrounded by the edging structure thus directly faces the region of the semiconductor component surrounded by the edging structure and has the same area and shape as the region of the semiconductor component surrounded by the edging structure.

The afore-mentioned embodiment of the invention prevents regions of the edging structure and of the first load terminal contact pad from facing each other directly, and thus advantageously spaces apart regions of the edging structure at the potential of the second load terminal from the first load terminal contact pad at the potential of the first load terminal.

In a further embodiment of the invention, at least one first through-contact runs parallel to a first straight line which forms a non-vanishing angle with a normal vector of the underside of the first circuit carrier.

In a further embodiment of the invention, the first load terminal contact pad is connected by at least one first through-contact to at least one first conductor path running inside the first circuit carrier, and this conductor path is connected by at least one further through-contact, what is referred to as a blind via, to at least one conductor path running on the top side of the first circuit carrier.

By way of obliquely running first through-contacts and/or blind vias, the two afore-mentioned embodiments of the invention enable an equalization of the connections and conductor paths on the top side of the first circuit carrier. As a result, required voltage spacings and air and creepage distances on the top side of the first circuit carrier can advantageously be adhered to and the circuit assembly can be made more compact, whereby material, in particular, can be saved.

In a further embodiment of the invention, the semiconductor component has a control terminal with a control terminal surface facing the first circuit carrier, which surface is arranged within the region of the semiconductor component surrounded by the edging structure. Further, the first circuit carrier has on its underside a control terminal contact pad which is electrically connected to the control terminal surface. Furthermore, the first circuit carrier has at least one second through-contact which connects the control terminal contact pad to at least one second conductor path which runs inside the first circuit carrier or on the top side of the first circuit carrier.

In a further embodiment of the invention, the control terminal contact pad is also arranged completely within the region of the underside of the first circuit carrier which corresponds to the region of the semiconductor component surrounded by the edging structure.

The two afore-mentioned embodiments of the invention relate to a circuit assembly with at least one semiconductor component which can be controlled by a control terminal (also referred to as a gate). Semiconductor elements of this kind are, for example, transistors and thyristors. These embodiments of the invention provide contacting of the control terminal which is analogous to the contacting of the first load terminal with the advantages mentioned above.

In a further embodiment of the invention, the control terminal contact pad extends into a region of the underside of the first circuit carrier which corresponds to the first load terminal surface. Analogously to the above statements, the region of the underside of the first circuit carrier, which corresponds to the first load terminal surface, designates a region of the underside of the first circuit carrier on which the first load terminal surface is indicated by a parallel displacement along a straight line parallel to a normal vector of the underside of the first circuit carrier.

The afore-mentioned embodiment of the invention takes account of the fact that the control terminal of a semiconductor component is often very small. In such a case it is expedient to embody the control terminal contact pad to be large enough that it projects into a region of the underside of the first circuit carrier which corresponds to the first load terminal surface. This also results in there always being sufficient overlap or cover between the control terminal contact pad and the control terminal surface in the case of insertion misalignment and the control terminal can thus be safely contacted. The first load terminal contact pad is accordingly smaller in design with such an embodiment of the control terminal contact pad.

In a further embodiment of the invention, a section of the control terminal contact pad, which extends into the region of the underside of the first circuit carrier corresponding to the first load terminal surface, has at least one region which cannot be contacted.

In a further embodiment of the invention, a region of the underside of the first circuit carrier located between the control terminal contact pad and the first load terminal contact pad has a region which cannot be contacted.

By way of the regions which cannot be contacted, the two afore-mentioned embodiments of the invention advantageously prevent an undefined run-off of bonding agent between the control terminal contact pad and the first load terminal contact pad and the risk of a short-circuit between the control terminal contact pad and the first load terminal contact pad or the first load terminal surface. A region which cannot be contacted is generated, for example, by way of coating with an additional material, such as solder resist, local influencing of the wettability, for example by laser oxidation or removal of existing material, for example by step etching.

In a further embodiment of the invention, every second through-contact runs parallel to a first through-contact. In particular, all first and second through-contacts can run parallel to one another. This simplifies the production and arrangement of the first and second through-contacts and prevents these through-contacts from crossing.

In a further embodiment of the invention, the second circuit carrier has an underside facing the semiconductor component, which underside is formed by a second electrically conductive layer, and an electrically insulating layer arranged between the first electrically conductive layer and the second electrically conductive layer. The Insulating layer advantageously enables electrical insulation of the underside of the second circuit carrier from its top side. In particular, it enables insulation with respect to a heat sink arranged on the underside. Such a heat sink is frequently used for dissipating heat from the circuit assembly. Increased robustness of the second circuit carrier with respect to thermal deformations, in particular, can be achieved by the second electrically conductive layer.

In a further embodiment of the invention, the first circuit carrier has on its underside a second load terminal contact pad which is electrically connected to the first electrically conductive layer of the second circuit carrier.

In a further embodiment of the invention, the first circuit carrier has at least one third through-contact which connects the second load terminal contact pad to at least one third conductor path which runs inside the first circuit carrier or on the top side of the first circuit carrier.

The two afore-mentioned embodiments of the invention enable the potential of the second load terminal to be supplied to the first circuit carrier and the second load terminal to be connected to at least one conductor path of the first circuit carrier.

In a further embodiment of the invention, at least one third through-contact runs parallel to a second straight line which forms a non-vanishing angle with a normal vector of the underside of the first circuit carrier, so a spacing of each third through-contact from each first through-contact in a plane parallel to the underside of the first circuit carrier increases as the spacing of this plane from the underside of the first circuit carrier increases. By way of obliquely running third through-contacts, this embodiment of the invention also enables an equalization of the connections and . . . conductor paths on the top side of the first circuit carrier in order to adhere to the required voltage spacings and air and creepage distances on the top side of the first circuit carrier and to make the circuit assembly more compact.

The above-described properties, features and advantages of this invention as well as the manner in which they are achieved will become clearer and more comprehensible in conjunction with the following description of exemplary embodiments which will be explained in more detail in conjunction with the drawings, in which:

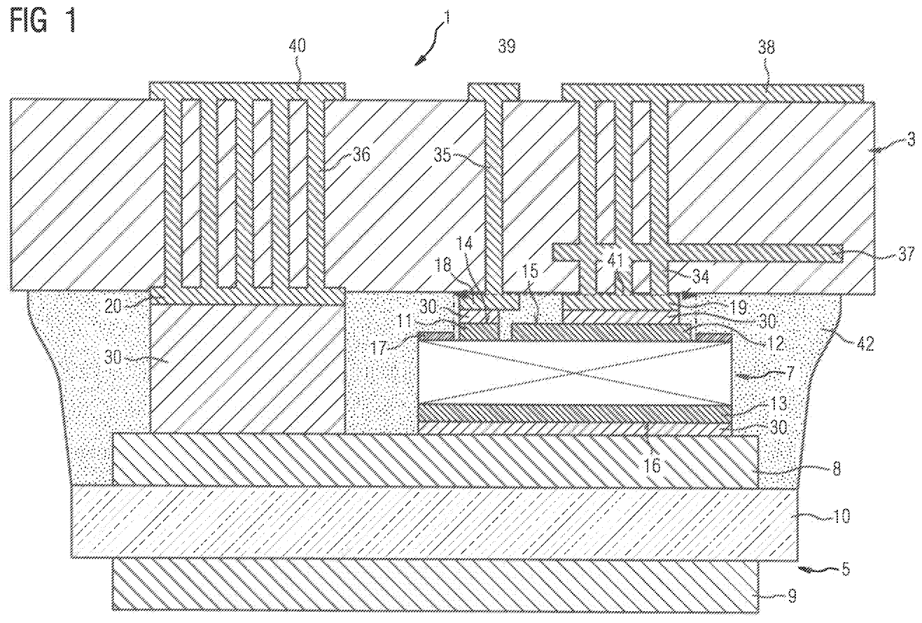

FIG. 1 shows a first schematic sectional representation of a first exemplary embodiment of a circuit assembly,

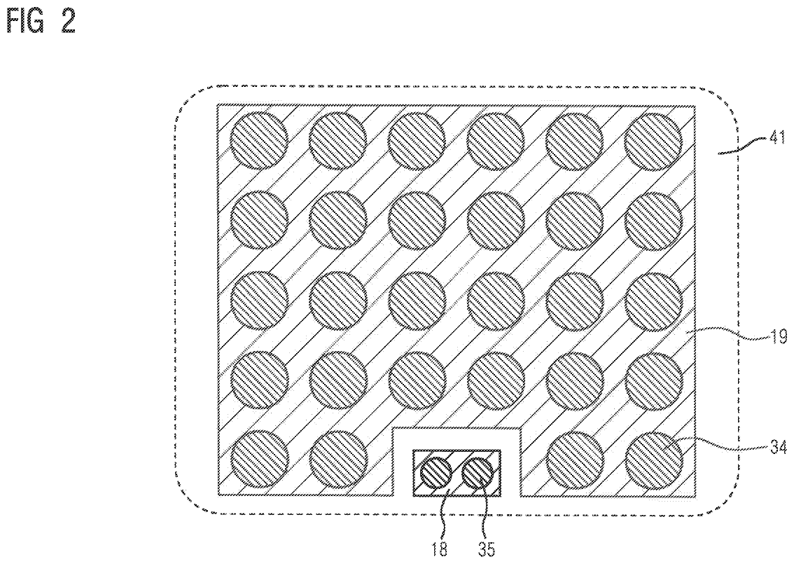

FIG. 2 shows a second schematic sectional representation of the circuit assembly shown in FIG. 1,

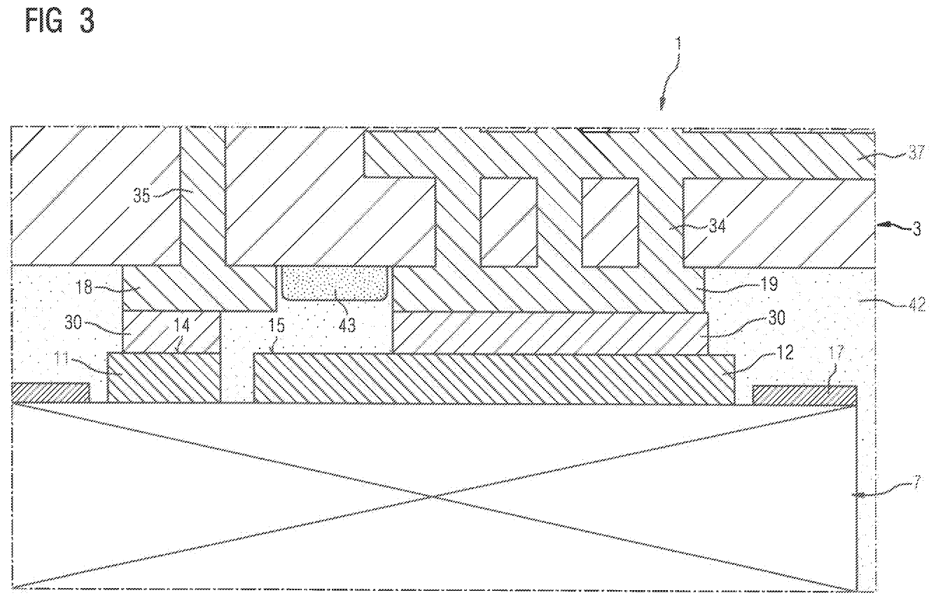

FIG. 3 shows a schematic sectional representation of a second exemplary embodiment of a circuit assembly,

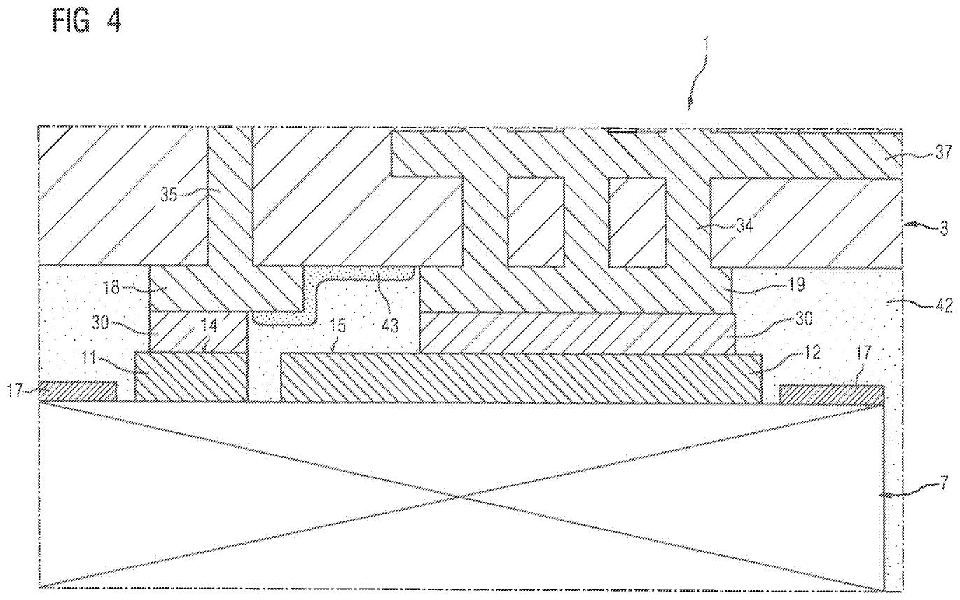

FIG. 4 shows a schematic sectional representation of a third exemplary embodiment of a circuit assembly,

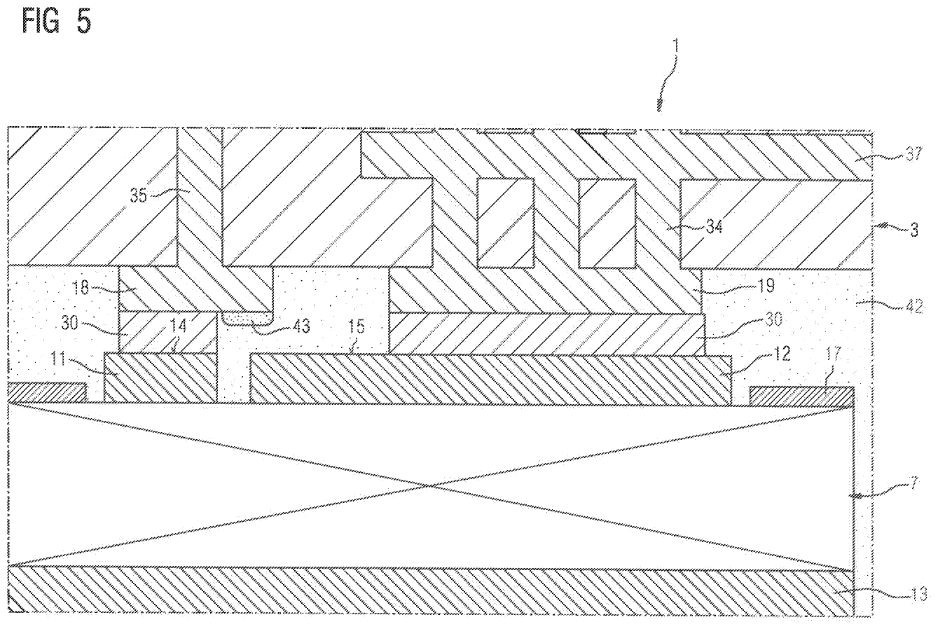

FIG. 5 shows a schematic sectional representation of a fourth exemplary embodiment of a circuit assembly,

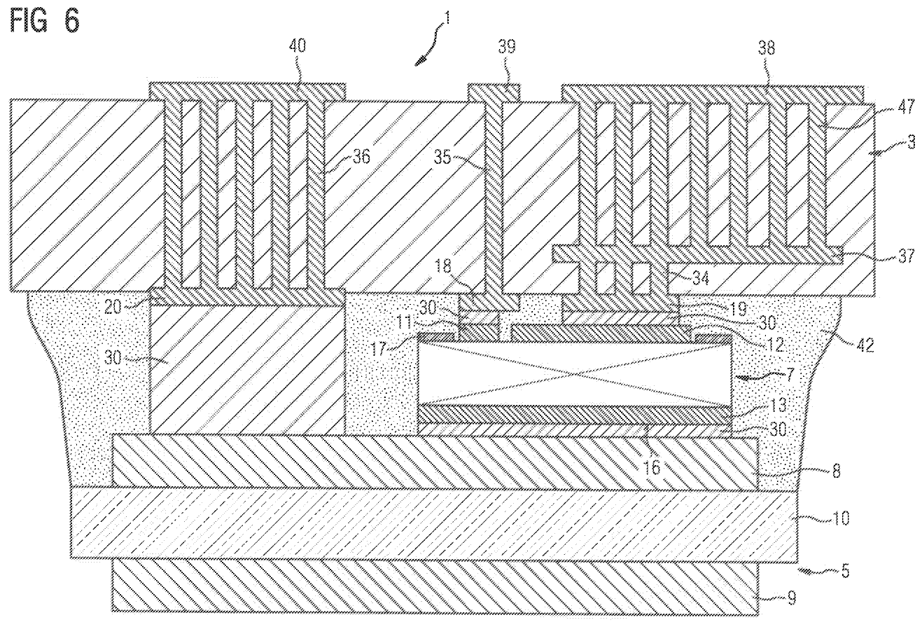

FIG. 6 shows a schematic sectional representation of a fifth exemplary embodiment of a circuit assembly,

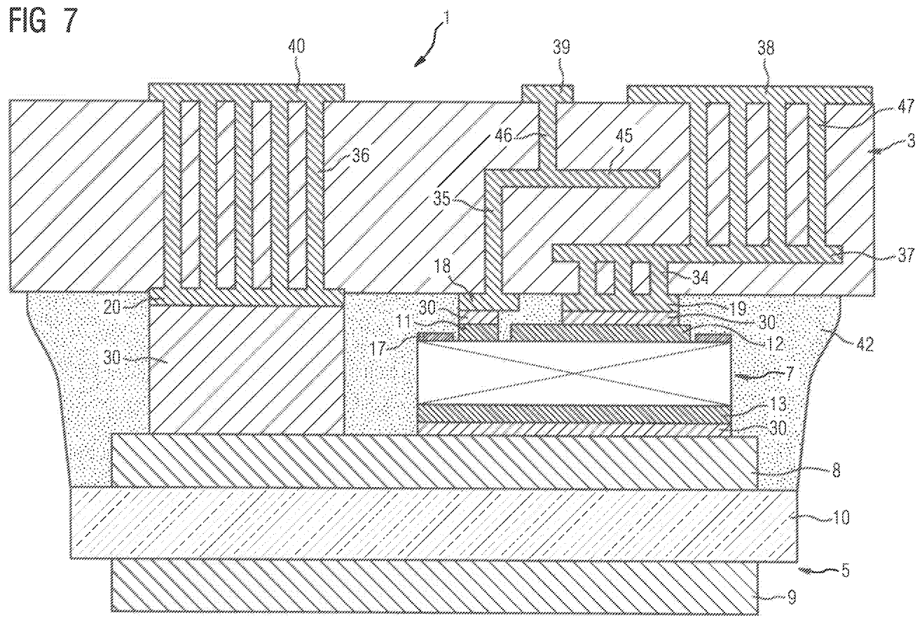

FIG. 7 shows a schematic sectional representation of a sixth exemplary embodiment of a circuit assembly,

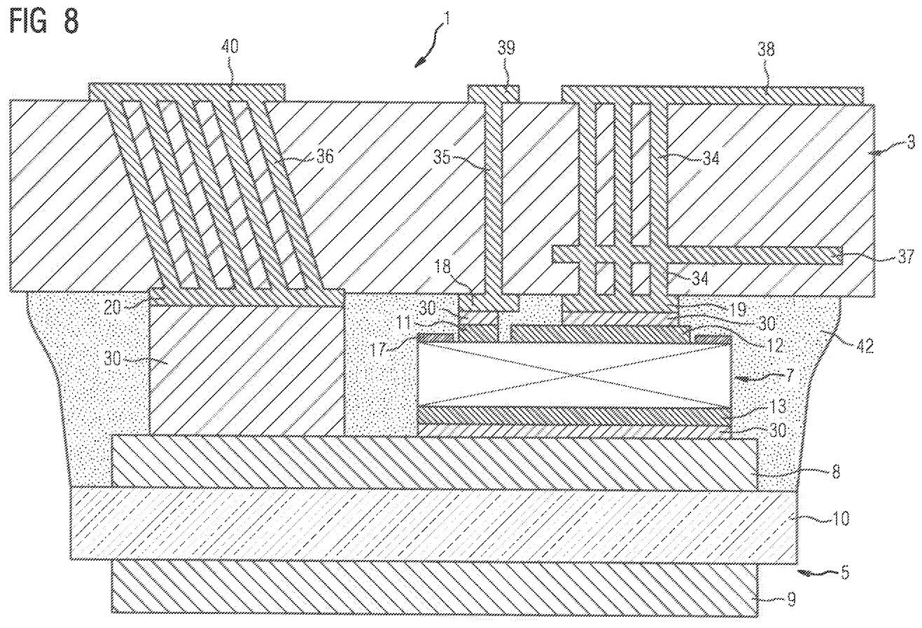

FIG. 8 shows a schematic sectional representation of a seventh exemplary embodiment of a circuit assembly,

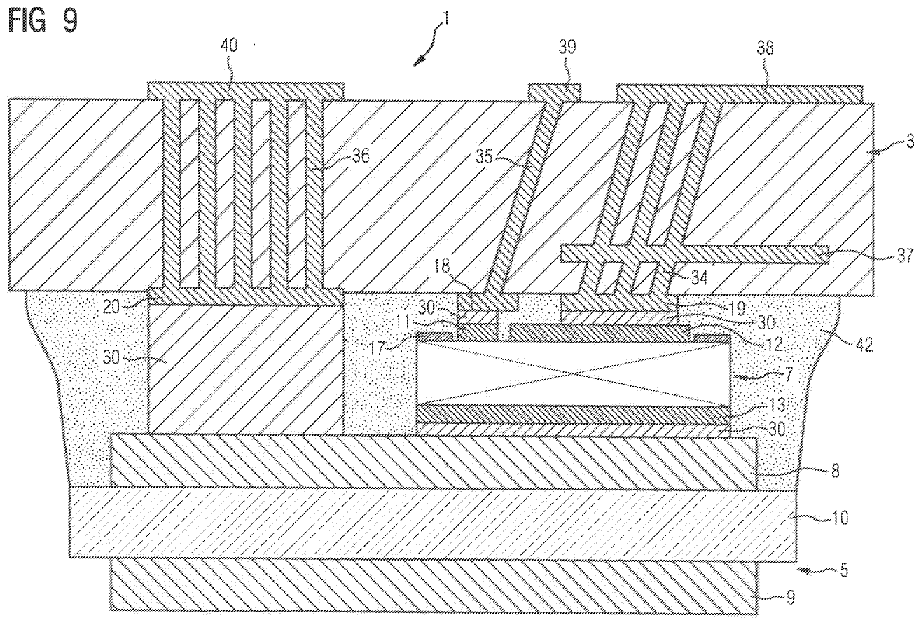

FIG. 9 shows a schematic sectional representation of an eighth exemplary embodiment of a circuit assembly,

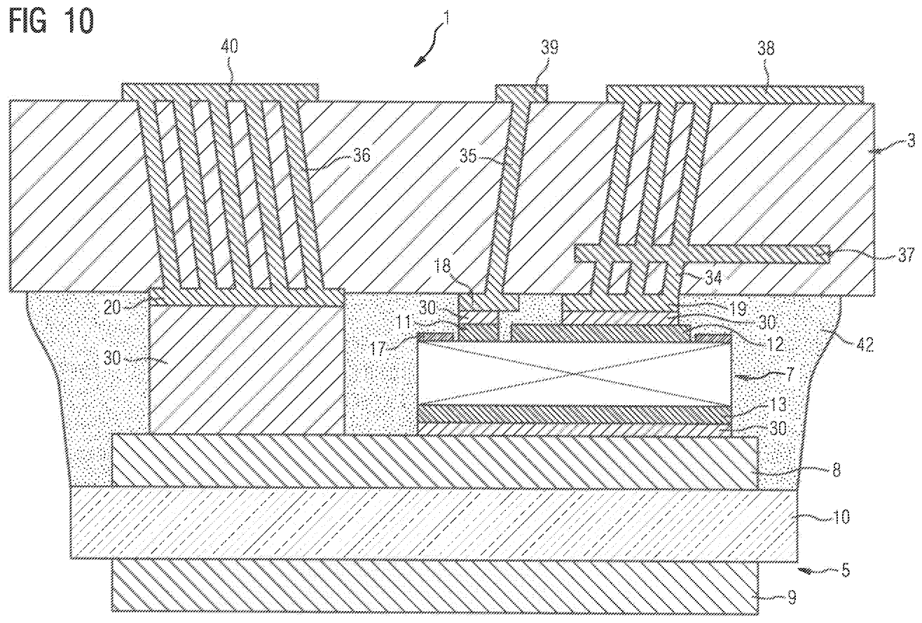

FIG. 10 shows a schematic sectional representation of a ninth exemplary embodiment of a circuit assembly.

Mutually corresponding parts are provided with the same reference numerals in the figures.

FIG. 1 (FIG. 1) shows a first schematic sectional representation of a first exemplary embodiment of a circuit assembly 1. The circuit assembly 1 comprises a first circuit carrier 3, a second circuit carrier 5 and a semiconductor component 7 arranged between the first circuit carrier 3 and the second circuit carrier 5.

In this exemplary embodiment, the first circuit carrier 3 is a multi-layer printed circuit board. The second circuit carrier 5 has a first electrically conductive layer 8, a second electrically conductive layer 9 and an electrically insulating layer 10 arranged between the two electrically conductive layers 8, 9. The first electrically conductive layer 8 forms a top side of the second circuit carrier 5 facing the semiconductor component 7. The second electrically conductive layer 9 forms an underside of the second circuit carrier 5 remote from the semiconductor component 7. The insulating layer 10 is, for example, a ceramic layer which is made, for example, from aluminum oxide, aluminum nitride or silicon nitride. For example, the second circuit carrier 5 is a DCB substrate (DCB: abbreviation for Direct Copper Bonded) or an AMB substrate (AMB: abbreviation für Active Metal Brazing).

In this exemplary embodiment the semiconductor component 7 is a transistor with a control terminal 11, a first load terminal 12 and a second load terminal 13. For example, the transistor is a bipolar transistor or a bipolar transistor with Insulated gate electrode (also referred to as an Insulated-Gate Bipolar Transistor, abbreviated to IGBT) whose first load terminal 12 is an emitter terminal and whose second load terminal 13 is a collector terminal. Alternatively, the transistor is, for example, a field effect transistor, in particular a metal-oxide semiconductor field-effect transistor (abbreviated to MOSFET) whose first load terminal 12 is a source terminal and whose second load terminal 13 is a drain terminal. In other exemplary embodiments the semiconductor component 7 can be, for example, a thyristor or a diode Instead of a transistor. In the case where the semiconductor component 7 is a diode, the control terminal 11 and the components of the circuit assembly 1 connected to it are omitted, however.

The control terminal 11 has a control terminal surface 14 facing the first circuit carrier 3. The first load terminal 12 has a first load terminal surface 15 facing the first circuit carrier. The second load terminal 13 has a second load terminal surface 16 facing the second circuit carrier 5 and which is larger than the first load terminal surface 15. Arranged around the control terminal surface 14 and the first load terminal surface 15 is an electrically insulating edging structure 17 which reduces a difference in potential between the two load terminals 12, 13.

On an underside facing the semiconductor component 7, the first circuit carrier 3 has a control terminal contact pad 18, a first load terminal contact pad 19 and a second load terminal contact pad 20. The control terminal contact pad 18 is electrically connected to the control terminal surface 14. The first load terminal contact pad 19 is electrically connected to the first load terminal surface 15. The second load terminal contact pad 20 and the second load terminal surface 16 are each electrically connected to the first electrically conductive layer 8 of the second circuit carrier 5. The electrical connections between these components are each produced by a bonding material 30, for example a soldering or sintering material, which electrically connects two components. The bonding material can depend on the connected components but for the sake of simplicity will be designated by the same reference numeral 30 in the figures for all of these electrical connections.

The first circuit carrier 3 has a plurality of through-contacts 34, 35, 36 which each connect the first load terminal contact pad 19, the control terminal contact pad 18 or the second load terminal contact pad 20 to at least one conductor path 37 to 40, which run inside, that is to say, in an inner layer of the first circuit carrier 3 or on a top side remote from the semiconductor component 7, that is to say, in a top-side outer layer of the first circuit carrier 3. FIG. 1 shows a plurality of first through-contacts 34 which connect the first load terminal contact pad 19 to a conductor path 37, which runs inside the first circuit carrier 3, and to a first conductor path 38, which runs on the top side of the first circuit carrier 3. Further, FIG. 1 shows a second through-contact 35, which connects the control terminal contact pad 18 to a second conductor path 39 running on the top side of the first circuit carrier 3, and a plurality of third through-contacts 36, which each connect the second load terminal contact pad 20 to a third conductor path 40 running on the top side of the first circuit carrier 3.

The control terminal contact pad 18 and the first load terminal contact pad 19 are arranged completely within a region 41 of the underside of the first circuit carrier 3 which corresponds to a region of the semiconductor component 7 surrounded by the edging structure 17.

A remaining spatial region between the underside of the first circuit carrier 3 and the second circuit carrier 5 is filled by a casting material 42, for example by a casting resin.

FIG. 2 (FIG. 2) shows a second schematic sectional representation of the circuit assembly 1 shown in FIG. 1 in the region 41 of the underside of the first circuit carrier 3, which corresponds to the region of the semiconductor component 7 surrounded by the edging structure 17. FIG. 2 shows that the control terminal contact pad 18 is surrounded by the first load terminal contact pad 19 on three sides, the contact pad-side ends of the first through-contacts 34 form a two-dimensional array on the first load terminal contact pad 19 and the control terminal contact pad 18 can be connected to more than just one second through-contact 35. In other exemplary embodiments the control terminal contact pad 18 can also be surrounded by the load terminal contact pad 19 on four sides, that is to say, be framed by the load terminal contact pad 19. Further, FIG. 2 shows that the first load terminal contact pad 19 and the control terminal contact pad 18 are arranged completely in the region 41 and that therefore the contact pad-side ends of the first through-contacts 34 and the second through-contacts 35 are also located completely in the region 41.

FIG. 3 (FIG. 3) shows a schematic sectional representation of a second exemplary embodiment of a circuit assembly 1. This exemplary embodiment differs from the exemplary embodiment shown in FIG. 1 merely in that a region of the underside of the first circuit carrier 3 located between the control terminal contact pad 18 and the first load terminal contact pad 19 has a region 43 which cannot be contacted, which is formed, for example, by solder resist. FIG. 3 therefore shows only one region of the circuit assembly 1 which encompasses this region of the underside of the first circuit carrier 3. This exemplary embodiment takes account of the fact that the control terminal contact pad 18 extends into a region of the underside of the first circuit carrier 3 which corresponds to the first load terminal surface 15. The extension of the control terminal contact pad 18 into the region of the underside of the first circuit carrier 3, which corresponds to the first load terminal surface 15, advantageously enlarges the size of the control terminal contact pad 18 and consequently enables safe electrical contacting of the control terminal contact pad 18 with the control terminal 11 and the second through-contacts 35. The region 43 which cannot be contacted prevents an undefined run-off of bonding agent between the control terminal contact pad 18 and the first load terminal contact pad 19 and the risk of a short-circuit between the control terminal contact pad 18 and the first load terminal contact pad 19. Instead of applying solder resist, the wettability for the bonding material 30 in the region of the underside of the first circuit carrier 3 located between the control terminal contact pad 18 and the first load terminal contact pad 19 can be reduced by way of a local additional treatment, for example by way of laser oxidation or step etching (the same applies to the exemplary embodiments shown in FIGS. 3 and 4).

FIG. 4 (FIG. 4) shows a schematic sectional representation of a third exemplary embodiment of a circuit assembly 1 analogous to FIG. 3. This exemplary embodiment differs from the exemplary embodiment shown in FIG. 3 merely in that the region 43 which cannot be contacted also comprises a region of the control terminal contact pad 18 facing the first load terminal contact pad 19 and the first load terminal surface 15 in order to also prevent the risk of a short-circuit between the control terminal contact pad 18 and the first load terminal surface 15.

FIG. 5 (FIG. 5) shows a schematic sectional representation of a fourth exemplary embodiment of a circuit assembly 1 analogous to FIGS. 3 and 4. This exemplary embodiment differs from the exemplary embodiments shown in FIGS. 3 and 4 merely in that the region 43 which cannot be contacted is only a region of the control terminal contact pad 18 facing the first load terminal surface 15 in order to prevent the risk of a short-circuit between the control terminal contact pad 18 and the first load terminal surface 15.

FIG. 6 (FIG. 6) shows a schematic sectional representation of a fifth exemplary embodiment of a circuit assembly 1. This exemplary embodiment differs from the exemplary embodiment shown in FIG. 1 merely in that conductor paths 37 running inside the first circuit carrier 3 and conductor paths 38 running on the top side of the first circuit carrier 3 are connected by additional through-contacts 47 (blind vias) which advantageously reduce current densities of currents between the conductor paths 37 and 38.

FIG. 7 (FIG. 7) shows an schematic sectional representation of a sixth exemplary embodiment of a circuit assembly 1. This exemplary embodiment differs from the exemplary embodiment shown in FIG. 6 merely in that the first through-contacts 34 each only run up to a conductor path 37 running inside the first circuit carrier 3, and that the second through-contacts 35 each only run to a further conductor path 45 running inside the first circuit carrier 3, which path is connected by a further through-contact 46 (a further blind via) to a second conductor path 39 running on the top side of the first circuit carrier 3.

FIG. 8 (FIG. 8) shows a schematic sectional representation of a seventh exemplary embodiment of a circuit assembly 1. This exemplary embodiment differs from the exemplary embodiment shown in FIG. 1 merely in that the third through-contacts 36 run parallel to a straight line which forms a non-vanishing angle with a normal vector of the underside of the first circuit carrier 3.

FIG. 9 (FIG. 9) shows a schematic sectional representation of an eighth exemplary embodiment of a circuit assembly 1. This exemplary embodiment differs from the exemplary embodiment shown in FIG. 1 merely in that the first through-contacts 34 and the second through-contacts 35 run parallel to a straight line which forms a non-vanishing angle with a normal vector of the underside of the first circuit carrier 3.

FIG. 10 (FIG. 10) shows a schematic sectional representation of a ninth exemplary embodiment of a circuit assembly 1. This exemplary embodiment differs from the exemplary embodiment shown in FIG. 1 merely in that the first through-contacts 34 and the second through-contacts 35 run parallel to a first straight line which forms a non-vanishing first angle with a normal vector of the underside of the first circuit carrier 3, and the third through-contacts 36 run parallel to a second straight line which forms a non-vanishing second angle with a normal vector of the underside of the first circuit carrier 3.

In the exemplary embodiments shown in FIGS. 8 to 10, the angles, which through-contacts 34, 35, 36 each form with a normal vector of the underside of the first circuit carrier 3, are selected in such a way that a spacing of each third through-contact 36 from each first through-contact 34 and each second through-contact 35 in a plane parallel to the underside of the first circuit carrier 3 increases as the spacing of this plane from the underside of the first circuit carrier 3 increases. As a result, required voltage spacings and air and creepage distances on the top side of the first circuit carrier 3 can advantageously be adhered to (for example, spacings of the conductor paths 38, 39 from the conductor paths 40) and the circuit assembly 1 can be made compact.

Although the invention has been illustrated and described in detail by preferred exemplary embodiments, it is not limited by the disclosed examples and a person skilled in the art can derive other variations herefrom without departing from the scope of the invention.

1.-12. (canceled)

13. A circuit assembly, comprising:
an at least two-layer first circuit carrier;
a second circuit carrier;
a semiconductor component arranged between the first circuit carrier and the second circuit carrier and comprising a first load terminal and a second load terminal, with the first load terminal including a first load terminal surface which faces the first circuit carrier and around which an electrically insulating edging structure is arranged, and with the second load terminal including a second load terminal surface which faces the second circuit carrier and Is sized larger than the first load terminal surface, said first load terminal surface being electrically connected to a first load terminal contact pad arranged on an underside of the first circuit carrier in facing relation to the semiconductor component, wherein the first circuit carrier has a first through-contact which connects the first load terminal contact pad to a first conductor path which runs inside the first circuit carrier or on a top side of the first circuit carrier remote from the semiconductor component;
a first electrically conductive layer formed on a top side of the second circuit carrier in facing relation to the semiconductor component and electrically connected to the second load terminal surface;
a second electrically conductive layer formed on an underside of the second circuit carrier, which underside is remote from the semiconductor component; and
an electrically insulating layer arranged between the first electrically conductive layer and the second electrically conductive layer,
wherein the first circuit carrier has an underside with a second load terminal contact pad which is electrically connected to the first electrically conductive layer of the second circuit carrier, and
wherein the first load terminal contact pad is arranged completely within a region of the underside of the first circuit carrier which region corresponds to a region of the semiconductor component surrounded by the edging structure.

14. The circuit assembly of claim 13, wherein the first through-contact runs parallel to a first straight line which forms a non-vanishing angle with a normal vector of the underside of the first circuit carrier.

15. The circuit assembly of claim 13, wherein the first conductor path runs Inside the first circuit carrier and is connected by a further through-contact to another conductor path which runs on the top side of the first circuit carrier.

16. The circuit assembly of claim 13, wherein the semiconductor component comprises a control terminal with a control terminal surface which faces the first circuit carrier and is arranged inside the region of the semiconductor component surrounded by the edging structure, and wherein the first circuit carrier comprises on the underside a control terminal contact pad which is electrically connected to the control terminal surface, said first circuit carrier having a second through-contact which connects the control terminal contact pad to a second conductor path which runs inside the first circuit carrier or on the top side of the first circuit carrier.

17. The circuit assembly of claim 16, wherein the control terminal contact pad is arranged completely within the region of the underside of the first circuit carrier.

18. The circuit assembly of claim 16, wherein the control terminal contact pad extends into a region of the underside of the first circuit carrier which region corresponds to the first load terminal surface.

19. The circuit assembly of claim 16, wherein the control terminal contact pad includes a section which extends into the region of the underside of the first circuit carrier corresponding to the first load terminal surface and has a region that cannot be contacted.

20. The circuit assembly of claim 16, wherein a region of the underside of the first circuit carrier is located between the control terminal contact pad and the first load terminal contact pad and has a region which cannot be contacted.

21. The circuit assembly of claim 16, wherein the second through-contact runs parallel to the first through-contact.

22. The circuit assembly of claim 13, wherein the first circuit carrier includes a third through-contact, which connects the second load terminal contact pad to a third conductor path which runs inside the first circuit carrier or on the top side of the first circuit carrier.

23. The circuit assembly of claim 22, wherein the third through-contact runs parallel to a second straight line which forms a non-vanishing angle with a normal vector of the underside of the first circuit carrier, so that a spacing of the third through-contact from the first through-contact in a plane parallel to the underside of the first circuit carrier increases with a spacing of the plane from the underside of the first circuit carrier.
